(19) United States
(12) Patent Application Publication
(10) Pub. No.: US 2025/0218469 A1
(43) Pub. Date: Jul. 3, 2025

(54) ELECTRONIC DEVICE

(71) Applicant: STMicroelectronics International N.V., Geneva (CH)

(72) Inventors: Laurent FAVENNEC, Villard Bonnot (FR); Simon JEANNOT, Grenoble (FR); Jean-Christophe GIRAUDIN, Saint-Nazaire-Les-Eymes (FR)

(73) Assignee: STMicroelectronics International N.V., Geneva (CH)

(21) Appl. No.: 19/004,036

(22) Filed: Dec. 27, 2024

(30) Foreign Application Priority Data
Jan. 2, 2024 (FR) FR2400012

(51) Int. Cl. G11C 5/06; H10B 63/00; H10B 63/10

(52) U.S. Cl. CPC G11C 5/06; H10B 63/10; H10B 63/30; H10N 70/882

(57) ABSTRACT

An electronic device includes—a semiconductor substrate having selection transistors arranged therein and a first interconnection stack including at least one level including first and second insulating layers having conductive tracks and first conductive vias defined therein. The electronic device includes a third insulating layer on the first stack and a second interconnection stack including at least one level including first and second insulating layers. The electronic device includes a plurality of memory cells arranged in the third insulating layer and at least one second conductive via extending through the entire height of the third insulating layer.

### CROSS-REFERENCE TO RELATED APPLICATION(S)

The present application is based on, and claims priority from, French patent application 2400012, filed on Jan. 2, 2024, entitled “Dispositif électronique,” which is incorporated by reference to the extent permitted by law.

### BACKGROUND

### Technical Field

The present disclosure generally concerns the field of electronic devices, and more particularly the field of electronic devices including a memory circuit based on a phase-change material and their manufacturing methods.

### Description of the Related Art

A phase-change material is a material having the ability to change crystalline state under the effect of heat, and more specifically to switch between a crystalline state and an amorphous state, which is more highly resistive than the crystalline state. This phenomenon is used to define two memory states, for example 0 and 1, differentiated by the resistance measured through the phase-change material.

There exists a need to improve electronic chips including a memory circuit including memory cells based on a phase-change material, and their manufacturing methods.

### BRIEF SUMMARY

An embodiment provides an electronic device including:
a semiconductor substrate having selection transistors arranged therein;
a first interconnection stack, arranged on the semiconductor substrate, including at least one level, each level including first and second insulating layers, having conductive tracks and first conductive vias defined therein; and
a third insulating layer, resting on the first interconnection stack;
a second interconnection stack, arranged on the third insulating layer, including at least one level, each level including first and second insulating layers, having the conductive tracks and the first conductive vias defined therein;
a plurality of memory cells arranged in the third insulating layer; and
at least one second conductive via extending along the entire height of the third insulating layer, so as to couple the conductive tracks and the first conductive vias of the first and second stacks.

According to an embodiment, each memory cell includes a resistive element in contact with a fourth layer made of a phase-change material, the seventh layer being topped with a fifth conductive layer.

According to an embodiment, the semiconductor substrate includes, from an upper surface, a sixth doped semiconductor layer of a first conductivity type, located on top of and in contact with a seventh doped semiconductor layer of a second conductivity type opposite to the first conductivity type.

According to an embodiment, the semiconductor substrate is topped with an eighth semiconductor layer including first doped areas of the second conductivity type, each of the first areas of the eighth semiconductor layer being coupled to a memory cell.

According to an embodiment, the sixth semiconductor layer, the seventh semiconductor layer, and the first areas of the sixth semiconductor layer form the selection transistors.

According to an embodiment, the eighth semiconductor layer includes second doped areas of the first conductivity type, each of the second areas of the eighth semiconductor layer being coupled to a set of first conductive vias and of conductive tracks running through the interconnection stack.

According to an embodiment, each of the first areas of the eighth semiconductor layer is coupled to a memory cell by a single third via extending along the entire height of the first stack.

According to an embodiment, each third via is in contact with the resistive element of the memory cell.

According to an embodiment, each of the first areas of the eighth semiconductor layer is coupled to a memory cell by conductive vias and conductive tracks of the first interconnection network and by a fourth via extending in the third layer and being in contact with the resistive element of the memory cell, each fourth via being made of the same material as the second vias.

According to an embodiment, the third layer is made of a material different from the material of the first and second insulating layers.

According to an embodiment, the material of the third layer has a dielectric constant higher than those of the materials of the first and second layers.

According to an embodiment, the height of the third layer is greater than the heights of the levels of the first and second stacks.

According to an embodiment, the level of the second stack closest to the third layer only includes conductive tracks in contact with the third via.

According to an embodiment, the conductive tracks of the first and second stacks laterally extend over a surface area greater than the surface area of the first conductive vias of the same level.

Another embodiment provides a method of manufacturing an electronic device including:
the forming of a semiconductor substrate having selection transistors arranged therein;
the forming of a first interconnection stack, arranged on the semiconductor substrate, including at least one level, each level including first and second insulating layers, having conductive tracks and first conductive vias defined therein;
the forming of a third insulating layer, resting on the first interconnection stack;
the forming of a plurality of memory cells arranged in the third insulating layer;
the forming of a second interconnection stack, arranged on the third insulating layer, including at least one level, each level including first and second insulating layers, having conductive tracks and first conductive vias defined therein; and
the forming of at least one second conductive via extending along the entire height of the third layer, so as to couple the conductive tracks and the first conductive vias of the first and second stacks.

In one embodiment, a device includes a semiconductor substrate including first doped regions of a first conductivity type and second doped regions of a second conductivity type. The device includes a first stack of first insulating layers on the semiconductor substrate, a second insulating layer on the first stack of first insulating layers, and a plurality of memory cells in the second insulating layer. The device includes a second stack of second insulating layers on the memory cells and a first group of first conductive interconnection structures in the first stack of first insulating layers including a plurality of first metal tracks and first conductive vias electrically coupled to a first doped region of the plurality of first doped regions. The device includes a plurality of second conductive vias each extending through an entirety of the first stack of insulating layers and coupling a respective memory cell to a second doped region and a third conductive via extending through an entirety of the second insulating layer and coupled to the first group of conductive interconnection structures.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1A and FIG. 1B illustrate two cross-section views, partial and simplified, of an electronic device according to an embodiment;

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, FIG. 2M, FIG. 2N, FIG. 2O, and FIG. 2P show steps of an example of a method of manufacturing the electronic device illustrated in FIG. 1A and in FIG. 1B;

FIG. 3 shows an electronic device according to another embodiment; and

FIG. 4 shows an electronic device according to another embodiment.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10%, preferably of plus or minus 5%.

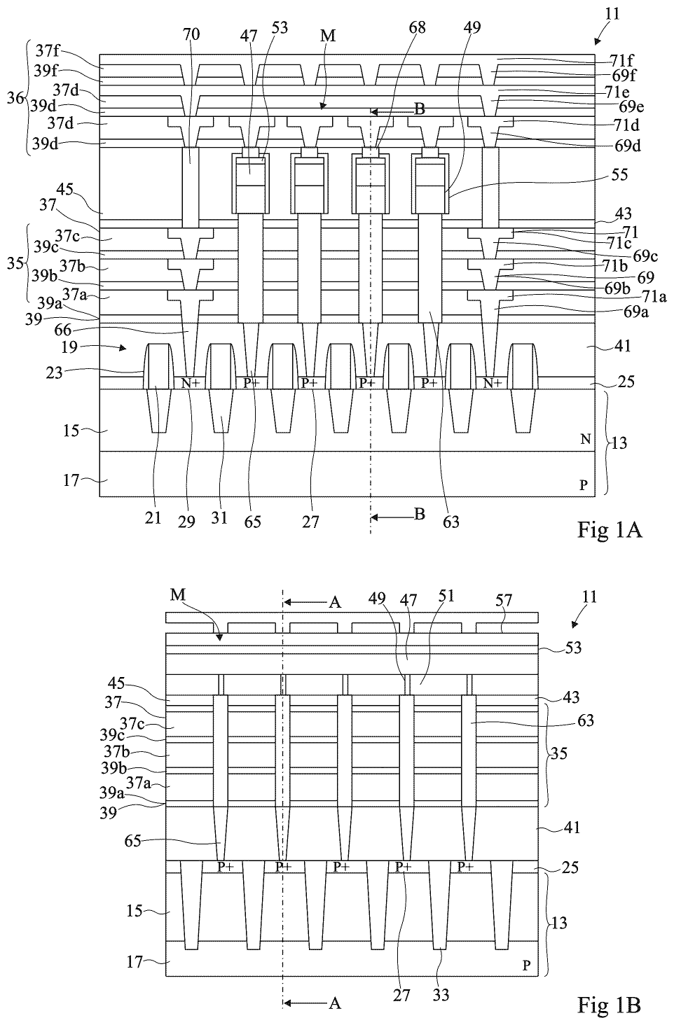

FIG. 1A and FIG. 1B illustrate two cross-section views, partial and simplified, of an electronic device 11, for example an electronic chip, according to an embodiment. FIG. 1A is a view along the cross-section plane AA of FIG. 1B, and FIG. 1B is a view along the cross-section plane BB of FIG. 1A.

More particularly, FIG. 1A and FIG. 1B illustrate a portion of a memory circuit of electronic chip 11. As an example, electronic chip 11 includes, in a portion not shown, a logic circuit adjacent to the memory circuit. The logic and memory circuits are, for example, manufactured simultaneously inside and on top of a same semiconductor substrate.

The electronic chip includes a semiconductor substrate 13. As an example, substrate 13 is made of silicon.

Substrate 13 includes, for example, a doped semiconductor layer 15 of a first conductivity type, for example of type N, for example, doped with arsenic or phosphorus atoms. Layer 15 rests, for example, on another semiconductor layer 17 of substrate 13, doped with a second conductivity type, opposite to the first conductivity type, for example of type P, for example doped with boron atoms.

As an example, chip 11 includes dummy gate patterns 19 arranged on the upper surface of layer 15, for example extending longitudinally in a first direction. Gate patterns 19 comprise, for example, a central portion 21 laterally surrounded by spacers 23. The central portion 21 of each gate pattern 19 is, for example, made of a semiconductor material, for example, of silicon, for example, of polysilicon. Spacers 23 are made of an electrically-insulating material, for example, of silicon nitride.

Gate patterns 19 are, for example, laterally separated by a semiconductor layer 25, for example formed by epitaxy from the upper surface of layer 15. Layer 25 is made of silicon, for example of single-crystal silicon.

Layer 25 includes, for example, first regions 27, for example doped with the second conductivity type, for example type P, and extending between certain gate patterns 19. Regions 27 are, for example, more heavily doped than layer 17. Each region 27 is, for example, topped with a memory cell M.

Memory cells M are for example organized, in top view, in an array of rows and columns. It is respectively spoken of word lines and of bit lines, each memory cell M being located at the intersection of a bit line and of a word line. As an example, the memory cells M illustrated in FIG. 1A are memory cells M of a same word line, while the memory cells illustrated in FIG. 1B are memory cells of a same bit line. In the example of FIG. 1A, gate patterns 19 extend in the same direction as the memory cells M illustrated in FIG. 1A, that is, in the bit line direction. In this example, gate patterns 19 extend, in top view, between the regions 27 of layer 25. In other words, in this example, in top view, any two consecutive regions 27 are separated from each other by one and only one gate pattern 19 extending along the entire length of said bit lines. In FIG. 1A, only four bit lines are shown and in FIG. 1B, only five word lines are shown. However, in practice, a memory circuit may comprise a number of bit lines and of word lines different from four and five respectively, for example greater than four and five.

Layer 25 further includes second regions 29, for example doped with the first conductivity type, for example of type N, and extending between other gate patterns 19. Regions 29 are, for example, more heavily doped than layer 15. Regions 29, unlike regions 27, are not topped with memory cells M.

Regions 29 and 27 are, for example, laterally delimited, in the word line direction, by gate patterns 19 and by first insulating trenches 31, for example super shallow trench isolation (SSTI) trenches. The first insulating trenches 31 prevent, for example, electric current leakages between two successive bit lines. The first trenches 31 are located, for example, under gate patterns 19. As an example, the first trenches 31 are linear and each gate pattern 19 is located on top of and in contact with a first trench 31. As an example, each first trench 31 longitudinally extends in the bit line direction, along the entire length of the bit lines. As an example, the first trenches 31 extend, vertically, in layer 15, from the upper surface of layer 15 across only part of the thickness of layer 15. The first insulating trenches 31 are, for example, filled with a dielectric material, for example silicon oxide. The depth of the first trenches 31 is, for example, in the range from 20 nm to 40 nm.

As an example, chip 11 includes second insulating trenches 33, for example shallow trench isolation (STI) trenches. Insulating trenches 31 and insulating trenches 33 are, for example, orthogonal and form a gate. The depth of insulating trenches 33 is, for example, greater than the depth of insulating trenches 31. Insulating trenches 33 extend, for example, from the upper surface of layer 15, into layer 15 and into part of layer 17. As an example, insulating trenches 33 enable to separate and thus to electrically insulate strips of layer 15 respectively vertically in line with each word line. As an example, each insulating trench 33 extends longitudinally in the word line direction, along the entire length of the word lines. Insulating trenches 33 are for example filled with a dielectric material, such as silicon oxide. The depth of trenches 33 is, for example, in the range from 300 nm to 400 nm.

In the example of FIGS. 1A and 1B, the structure formed by layers 15, 17 and 21 and gate patterns 19 is topped with an interconnection stack, or network. The interconnection stack is divided into two parts: a first interconnection stack 35 and a second interconnection stack 36. In this example, interconnection stack 35 is formed between substrate 13 and memory cells M. The interconnection stack extends, for example, over the entire chip 11. Interconnection stack 35 is for example formed of a succession of levels, each level including an insulating layer 37 and an insulating layer 39. Layers 37 and 39 are made of different materials, for example.

Interconnection stack 35 is formed, for example, on an insulating layer 41 covering the upper surface of layer 25 and the upper surface of gate pattern 19. The layer 41 extends over the entire chip 11, for example. Insulating layer 41 is, for example, in contact with the upper surface of layer 25 and of gate patterns 19. Insulating layer 41 for example covers the entire upper surface of layer 25. Insulating layer 41 has a thickness in the range from 120 nm to 200 nm, for example in the range from 140 nm to 180 nm.

Interconnection stack 35 is, for example, formed on the upper surface of insulating layer 41 and covers, for example, the entire surface of insulating layer 41. Interconnection stack 35 includes, for example, an insulating layer 39a formed on top of and in contact with the upper surface of insulating layer 41. Interconnection stack 35 further includes an insulating layer 37a formed on insulating layer 39a. Insulating layer 37a is for example formed over the entire surface of insulating layer 39a. As an example, insulating layer 37a is in contact, by its lower surface, with the upper surface of insulating layer 39a. Layers 39a and 37a form a level of the interconnection stack.

Interconnection stack 35 may further comprise additional levels formed on top of and in contact with insulating layer 37a. In FIGS. 1A and 1B, interconnection stack 35 includes two additional levels, for example respectively formed of layers 37b and 39b and of layers 37c and 39c. In practice, the number of levels in interconnection stack 35 may be different from three, for example greater than three.

As an example, interconnection stack 35 has a thickness in the range from 100 nm to 600 nm, for example in the range from 200 nm to 500 nm, for example in the order of 300 nm. For example, the levels of the interconnection stack have substantially the same thickness.

Interconnection stack 35 is for example topped with an insulating layer 43. Insulating layer 43 is for example formed on top of and in contact with interconnection stack 35 and more particularly on top of and in contact with insulating layer 37c. Insulating layer 43 extends, for example, over the entire surface of interconnection stack 35.

As an example, insulating layers 41 and 37 are made of a material having a low dielectric constant, for example a material having a dielectric constant (corresponding to the permittivity of said material relative to the permittivity of vacuum) smaller than 5, for example smaller than 4. Insulating layers 37 are for example made of SiOCH or of porous SiOCH. As an example, insulating layers 39 and 43 are made of silicon carbonitride (SiCN), of silicon nitride (SiN), or of SiCH.

Insulating layer 43 is for example topped with an insulating layer 45. Layer 45 is for example made of a single material. Layer 45 is for example made of a homogeneous material. Insulating layer 45 is for example made of a material different from the material of layers 37. Insulating layer is for example made of a material different from the material of layers 39 and 43. Insulating layer 45 is for example made of a material having a dielectric constant greater than 3.7, or of silicon dioxide (SiO₂). As an example, insulating layer 45 is formed on top of and in contact with the upper surface of insulating layer 43. Layer 45 for example has a thickness greater than the thickness of the levels of the interconnection stack, for example of all the levels of stack 35. Layer 45 for example has a substantially constant thickness. The thickness of layer 45 is, for example, in the range from 160 nm to 500 nm, for example in the range from 180 nm to 240 nm. Layer 45 preferably extends over the entire chip, including over the regions of the chip including logic circuits.

Layer 45 is covered, preferably fully covered, by interconnection stack 36. Thus, for example, interconnection stack 35 is formed on layer 45, for example on memories M. Interconnection stack 36 extends, for example, over the entire chip 11. Interconnection stack 36 is formed, for example, by a succession of levels, each level including an insulating layer 37 and an insulating layer 39.

Interconnection stack 36 is for example formed on an insulating layer 45 and for example covers the entire surface of insulating layer 45. Interconnection stack 36 includes, for example, an insulating layer 39d formed on top of and in contact with the upper surface of insulating layer 45. Interconnection stack 36 further includes an insulating layer 37d formed on insulating layer 39d. Insulating layer 37d is for example formed over the entire surface of insulating layer 39d. As an example, insulating layer 37d is in contact, by its lower surface, with the upper surface of insulating layer 39d. Layers 39d and 37d form a level of interconnection stack 36.

Interconnection stack 36 may, for example, comprise additional levels formed on top of and in contact with insulating layer 37d. In FIGS. 1A and 1B, interconnection stack 36 includes two additional levels, for example respectively formed of layers 37e and 39e and of layers 37f and 39f. In practice, the number of levels in interconnection stack 36 may be different from three, for example greater than or equal to one.

As an example, interconnection stack 36 has a thickness in the range from 100 nm to 600 nm, for example in the range from 200 nm to 500 nm, for example in the order of 300 nm. For example, the levels of the interconnection stack have substantially the same thickness, for example the same thickness as the levels of interconnection stack 35.

As an example, the insulating layers 37 of stack 36 are made of a material having a low dielectric constant, for example a material having a dielectric constant (corresponding to the permittivity of said material relative to the permittivity of vacuum) smaller than 5, for example smaller than 4. Insulating layers 37 are for example made of SiOCH or of porous SiOCH. As an example, insulating layers 39 are made of silicon carbonitride (SiCN), of silicon nitride (SiN), or of SiCH.

Memory cells M are formed in insulating layer 45. Preferably, the memory cells are entirely located in layer 445.

As an example, each memory cell M includes a layer 47 made of a phase-change material, for example a chalcogenide material, for example an alloy of germanium, antimony, and tellurium (GeSbTe) known as GST. Layer 47 forms a variable-resistance resistive element. Layer 47 of phase-change material has a thickness in the range from 30 nm to 100 nm, for example, in the order of 50 nm. In the embodiment of FIGS. 1A and 1B, the cells M of a same bit line, preferably all the cells M of a same bit line, comprise a common layer 47. Layer 47 thus extends, in layer 45, in the bit line direction.

In one embodiment, the layer 45 has a height, for example a maximum height, higher than the height of layer 47, for example higher than the height of the stack comprising the resistive element 49, layer 47 and the layer 53. In one embodiment, the layer 45 has a height, for example a maximum height, higher than the height of the memory cell M.

In each memory cell M, layer 47 is, for example, controlled by a metallic resistive heating element 49 located under layer 47, for example in contact, by its upper surface, with the lower surface of layer 47, and laterally surrounded by a layer made of a thermal insulator 51. In other words, each memory cell includes a resistive element 49 in contact with the lower surface of layer 47 at the location of said memory cell. Elements 49 are for example separated from one another by insulating layer 51. For example, layer 51 is made of the same material as layer 45. As an example, layer 51 is made of silicon carbonitride. As an example, heating element 49 has a thickness in the range from 30 nm to 170 nm, for example in the order of 80 nm.

Layer 47 of phase-change material is, for example, topped with conductive tracks, or metallizations, 53, for example made of a conductive material, for example made of metal. As an example, in each memory cell M, resistive element 49 and track 53 respectively form a lower electrode and an upper electrode of memory cell M.

As an example, the memory cells M of a same bit line are topped with a same track 53. In other words, the upper electrodes 53 of the memory cells M of a same bit line are interconnected. In other words, in the example of FIGS. 1A and 1B

Each memory cell M is for example covered by an insulating layer 55 protecting, for example, layer 47 from oxidation. Insulating layer 55 is for example made of a nitride, for example of silicon nitride. Layer 55 preferably covers at least partially the upper surface of layer 53 and covers for example at least partially, preferably entirely, the side walls of layers 47, 51, 53 and of elements 49.

In the example of FIGS. 1A and 1B, for each memory cell M, the area 27 located vertically in line with said memory cell M, layer 15 (and area 29), and layer 17 define a bipolar transistor, here of PNP type, for selecting the memory cell. Each memory cell M is for example associated with a bipolar transistor. In this example, region 27 forms an emitter region of the transistor, region 15 (and area 29) forms a base region of the transistor, and layer 17 forms a collector region of the transistor. As an example, the collector is common to all the transistors of the array and is, for example, connected to ground. In this example, base region 15 is common to all the transistors of a same word line of the memory circuit.

Each memory cell M is electrically connected to the selection transistor with which it is associated via a conductive via 63 running through the entire thickness of interconnection stack 35. As an example, via 63 runs through all the insulating layers 39 and 37 of interconnection stack 35.

As an example, via 63 is in contact, by its upper surface, with the lower surface of the resistive heating element 49 of memory cell M. Via 63 is for example in contact, by its lower surface, with another conductive via 65, itself in contact with the upper surface of layer 25. Thus, the via 63 of each memory cell M partially extends through layer 45, more precisely through the portion of layer 45 located under element 48, and extends through interconnection stack 35, preferably through the entire stack 35.

As an example, for each memory cell M, the corresponding via 63 electrically couples the heating element 49 of the memory cell to the underlying region 27, via a via 65.

Conductive via 63 is for example made of a metallic material. Conductive via 63 is for example made of tungsten. As a variant, conductive via 63 is for example made of cobalt or of copper. Conductive via 63 has, for example, a width, taken in the plane of FIG. 1A and in the plane of FIG. 1B, in the range from 40 nm to 100 nm, for example in the order of 70 nm.

Conductive via 65 for example runs through insulating layer 41. Conductive via 65 is for example flush, by its lower surface, with the lower surface of insulating layer 41, and by its upper surface with the upper surface of insulating layer 41. Thus, via 41 extends along the entire height of layer 41. Conductive via 65 is for example in contact, by its lower surface, with the upper surface of layer 25 and more particularly with region 27. Conductive via 65 is for example in contact, by its upper surface, with the lower surface of conductive via 63. Conductive via 65 is for example made of a metallic material, for example of tungsten.

Each level of interconnection stack 35, 36 includes, for example, conductive vias 69 and conductive tracks 71. Conductive tracks 71 are flush with the upper surface of layer 37 and extend in layer 37. Conductive vias 69 are in contact with a conductive track 71 at the same level. Conductive vias 69 extend from the lower surface of the conductive track 71 of the same level to the lower surface of the layer 39 of the same level. Conductive tracks 71 and vias 69 thus enable to form electrical couplings across the levels of the interconnection stack. Conductive tracks 71 and conductive vias 69 are for example made of metal, for example of copper or of tungsten.

More specifically, conductive tracks 71a are flush with the upper surface of layer 37a and extend in layer 37a. Conductive vias 69a extend from tracks 71a to the lower surface of layer 39a, through layer 39a. Similarly, conductive tracks 71b, respectively 71c, respectively 71d, respectively 71e, respectively 71f, are flush with the upper surface of layer 37b, respectively 37c, respectively 37d, respectively 37e, respectively 37f, and extend in layer 37b, respectively 37c, respectively 37d, respectively 37e, respectively 37f. Conductive vias 69b, respectively 69c, respectively 69d, respectively 69e, respectively 69f, extend from tracks 71b, respectively 71c, respectively 71d, respectively 71e, respectively 71f, to the lower surface of layer 39b, respectively 39c, respectively 39d, respectively 39e, respectively 39f, through layer 39b, respectively 39c, respectively 39d, respectively 39e, respectively 39f.

As an example, conductive tracks 71 laterally extend over a surface area in the range from 60 nm by 60 nm to 100 nm by 100 nm, for example in the order of 80 nm by 80 nm. As an example, conductive tracks 71 extend laterally over a surface area greater than the surface area of vias 69 and of conductive via 63.

Each memory cell M is coupled to a track 71 and to a conductive via 69 by a conductive element 68. Preferably, each memory cell M is coupled to the conductive tracks and vias of the bottom level of interconnection stack 36, that is, the level closest to layer 45.

Each element 68 extends from the upper surface of layer 45 to the upper surface of layer 53. Each element 68 thus runs through a portion of layer 45 and layer 55 so as to be in contact with layer 53. Device 11 for example includes one element 68 for each bit line. Each element 68 for example extends along at least part of the length of layer 5, for example along the entire length of layer 53, for example at least in front of each memory cell M.

Elements 68 are for example made of metal. Elements 68 are, for example, made of a material different from the material of tracks 71 and of vias 69.

As a variant, each element 68 may be replaced with conductive vias, not shown, for example made of the same material as element 68. Each via, not shown would extend, like element 68, from the upper surface of layer 53 to the upper surface of layer 45. Each memory cell M would be located vertically in line with a conductive via, not shown.

Each element 68 is for example in contact with the lower surface of at least one via 69d, for example with as many vias 69d as the bit line includes memory cells M. Said vias 69d in contact with the same element 68 are preferably coupled together by a track 71d. Thus, the upper electrodes of the memory cells of a same bit line are coupled together by a track 71d of the interconnection stack.

Layer 41 includes vias 66. Layer 41 for example includes as many vias 66 as layer 25 includes regions 29. Each via 66 is in contact with a region 29. In other words, each via 66 extends between a region 29 and the upper surface of layer 41.

The second regions 29 of layer 25 are for example coupled to conductive tracks 71e or 71f. Conductive tracks 71e or 71f are for example made of copper. Conductive tracks 71e or 71f correspond, for example, to the contacting areas of the word lines.

Each region 29 is coupled to a conductive track 71e or 71f by a via 66, running through insulating layer 41, by a succession of vias 69 and of conductive tracks 71 running through interconnection stack 35, by a conductive via 70, running through insulating layer 43 and insulating layer 45, and by a succession of vias 69 and of conductive tracks 71 running through interconnection stack 36.

In other words, in the example of FIGS. 1A and 1B, each region 29 is in contact with the lower surface of a via 66. The upper surface of said via 66 is in contact with the lower surface of a via 69a, via 69a being in contact with a track 71a. The upper surface of track 71a is in contact with a via 69b, via 69b being in contact with a track 71b. The upper surface of track 71b is in contact with a via 69c, via 69c being in contact with a track 71c. The upper surface of track 71c is in contact with a lower surface of via 70. The upper surface of via 70 is in contact with a via 69d, via 69d being in contact with a track 71d. The upper surface of track 71d is in contact with a via 69e, via 69e being in contact with a track 71e. The upper surface of track 71e is in contact with a via 69f, via 69f being in contact with a track 71f. In the example of FIGS. 1A and 1B, the regions 29 of a same word line are coupled together by common tracks 71e and 71f.

Vias 70 extend, for example, from the upper surface of layer 45 to the upper surface of a track 71 located in the upper level of interconnection stack 35, that is, the level closest to layer 45. In other words, each via 70 extends at least along the entire height of layer 45, preferably along the height of layer 45 and of layer 43. Each via 70 for example has a height greater than the height of vias 69.

Each via 70 corresponds, for example, to a single via. The side walls of vias 70 are for example planar. Vias 70 thus comprise no landings. Each via 70 for example has substantially constant lateral dimensions.

The presence of layer 45, including the memory cells and vias 70, and in particular the absence of a conductive track in layer 45, enable to decrease risks of parasitic capacitance and thus enables to use different materials for layer 45 and for the layers of stack 35.

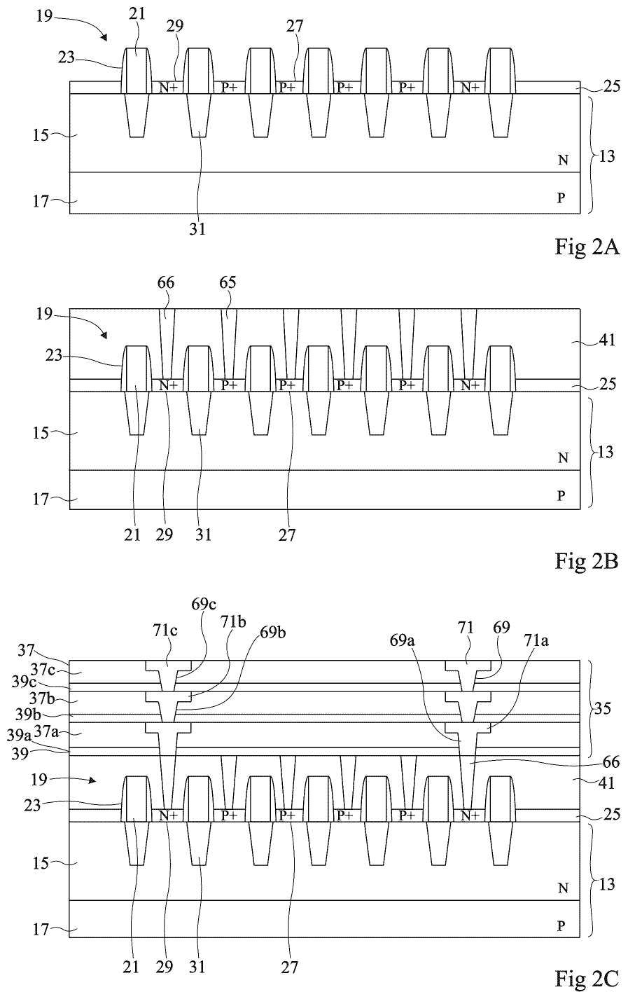

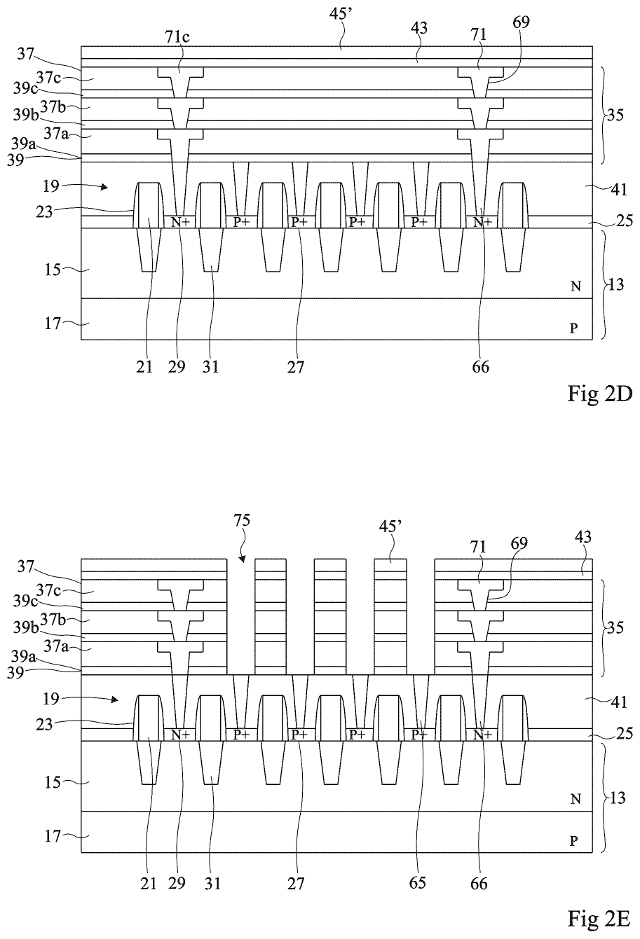

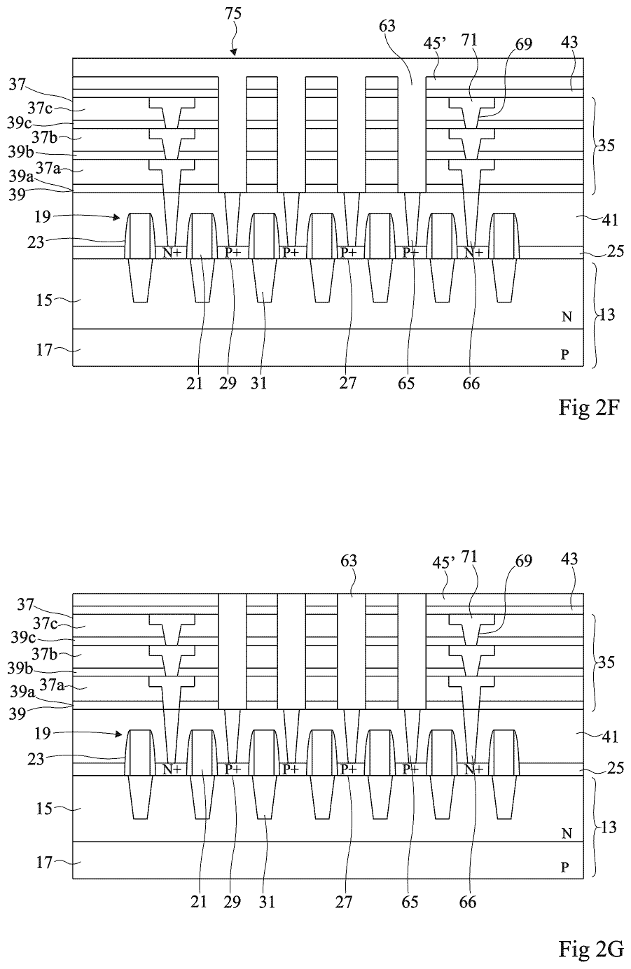

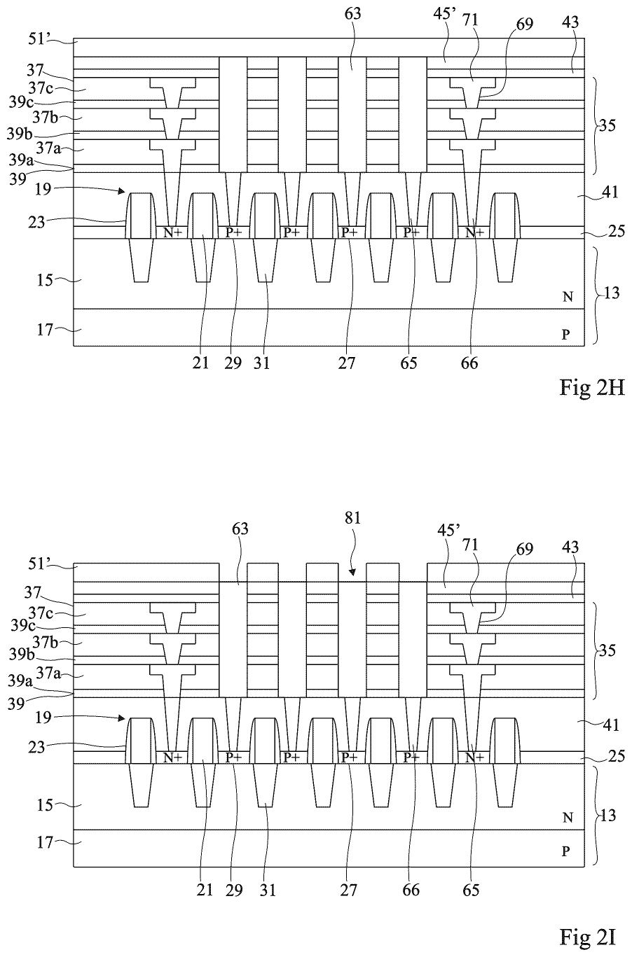

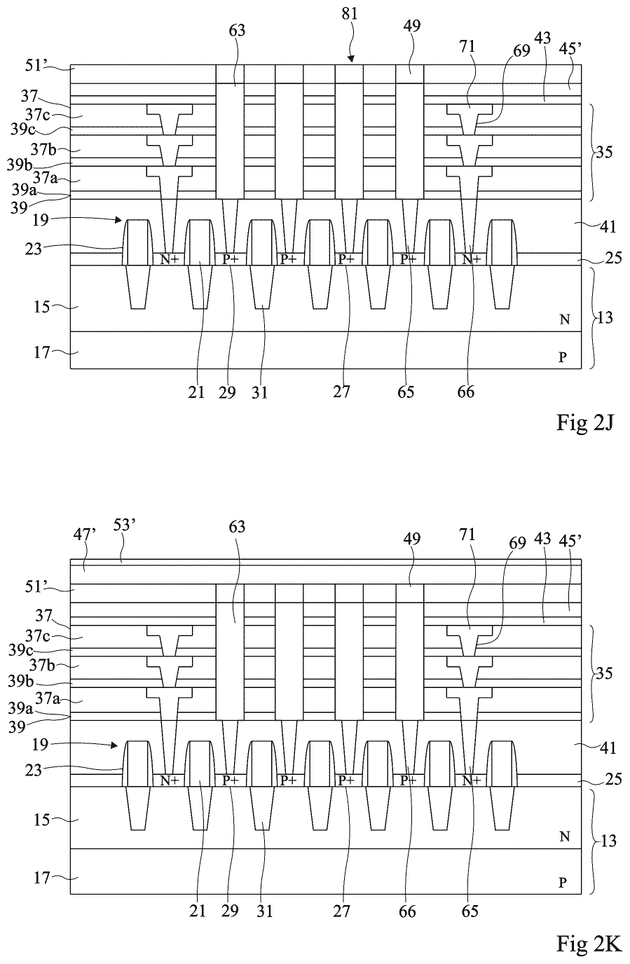

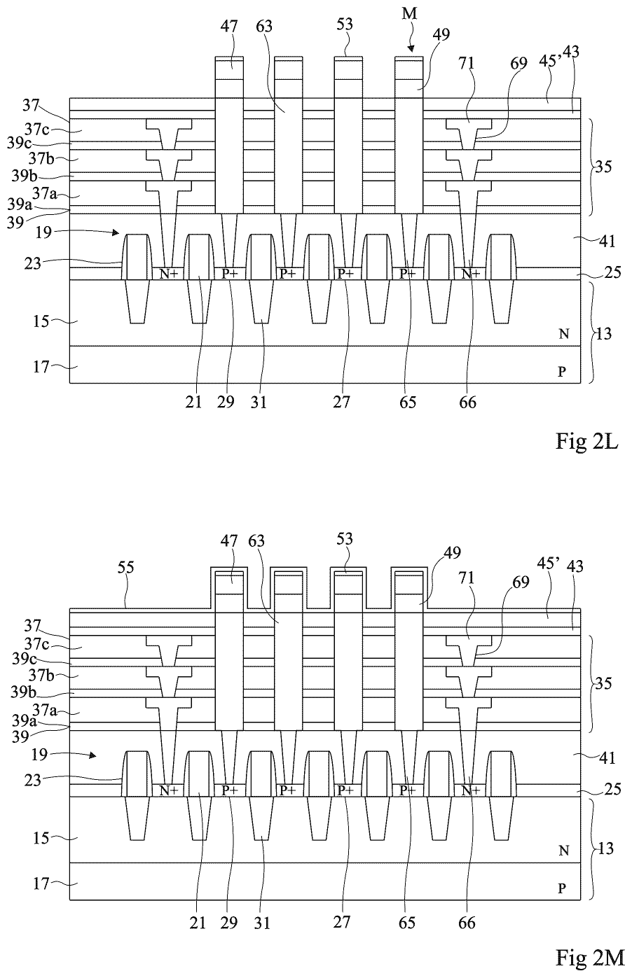

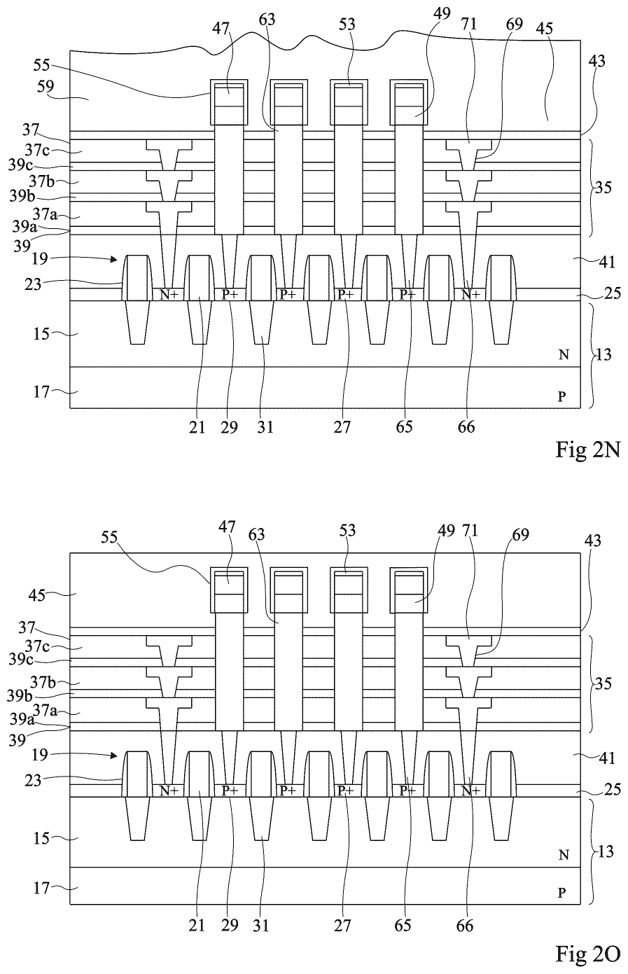

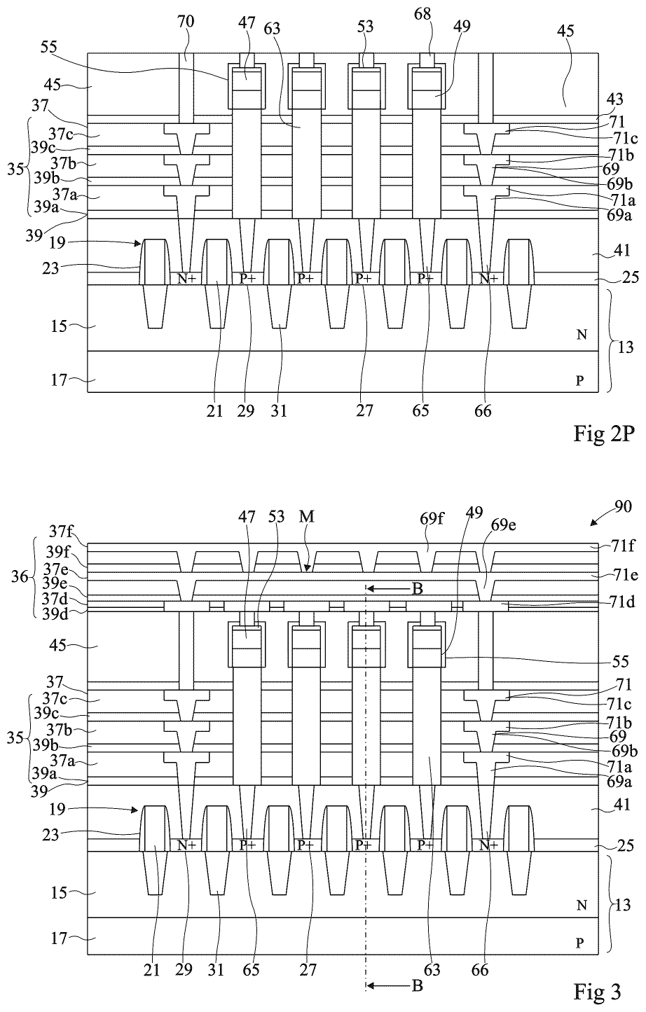

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, FIG. 2M, FIG. 2N, FIG. 2O, and FIG. 2P show steps of an example of a method of manufacturing the electronic device illustrated in FIG. 1A and in FIG. 1B.

FIG. 2A shows a cross-section view, partial and simplified, of an initial structure including on semiconductor substrate 13:
semiconductor layer 25 including regions 27 and 29; and
gate patterns 19 including a central portion 21 surrounded by spacers 23.

FIG. 2B illustrates a cross-section view, partial and simplified, of a structure obtained at the end of a step of forming of insulating layer 41 on the upper surface of the initial structure illustrated in FIG. 2A and of forming of vias 65 and 66 in insulating layer 41.

FIG. 2C illustrates a cross-section view, partial and simplified, of a structure obtained at the end of a step of forming of interconnection stack 35 on the upper surface of the structure illustrated in FIG. 2B and of forming of vias 69 and of conductive tracks 71 in interconnection stack 35. This step is for example carried out according to a damascene method, for example according to a double damascene method, during which the conductive vias 69 and the conductive tracks 71 of a same level of stack 35 are simultaneously formed.

During this step, there is formed, in a first phase, insulating layer 39a on the upper surface of the structure illustrated in FIG. 2B, and then insulating layer 37a on the upper surface of insulating layer 39a.

Layers 39a and 37a are, in a second phase, locally etched and then filled with a metallic material to form conductive vias 69a and conductive tracks 71a.

The different upper levels of interconnection stack 35 are for example similarly formed one after the other.

FIG. 2D illustrates a cross-section view, partial and simplified, of a structure obtained at the end of a step of forming of conductive layer 43 on the upper surface of the structure illustrated in FIG. 2C and of forming of an insulating layer 45′ on the upper surface of conductive layer 43. Conductive layer 43 is formed, for example, in contact with insulating layer 37c and with the upper surface of conductive track 71c. As an example, insulating layer 45 is formed in contact with conductive layer 43.

Layer 45′ corresponds to the portion of layer 45 located under memory cells M. Thus, layer 45 is made of the same material as the layer 45 of FIGS. 1A and 1B.

FIG. 2E shows a cross-section view, partial and simplified, of a structure obtained after a step of forming of openings 75 running through layers 43 and 45′ and interconnection stack 35 vertically in line with areas 27. As an example, openings 75 emerge onto the upper surfaces of vias 65. Openings 75 are for example formed by etching, for example by wet etching. As an example, openings 75 are etched through an etch mask, not shown in FIG. 2E. As an example, the etch mask is made of resin. The etch mask is, for example, deposited and structured prior to the step of etching of openings 75 by photolithography. As an example, openings 75 may not have perfectly rectilinear and vertical flanks. Indeed, layers 37 and 39 are of different natures and thus do not have the same etching speed. It can thus be provided for openings 75 to be wider in layers 37.

FIG. 2F illustrates a cross-section view, partial and simplified, of a structure obtained at the end of a step of deposition of a layer 77 made of the material of vias 63 on the upper surface of the structure illustrated in FIG. 2E. More particularly, during this step, layer 77 is formed so that it entirely covers the upper surface of the structure illustrated in FIG. 2E and more precisely the upper surface of layer 45 and so as to fill openings 75.

FIG. 2G shows a cross-section view, partial and simplified, of a structure obtained at the end of a step of planarization or of polishing of the upper surface of the structure illustrated in FIG. 2F, to expose the upper surface of layer 45. In other words, during this step, the excess layer 77 is removed, so as to only leave layer 77 in openings 75 to form vias 63. As an example, this step is carried out by mechanical planarization, for example by chemical mechanical planarization (CMP). At the end of this stage, vias 63 are flush with the upper surface of layer 45′.

FIG. 2H illustrates a cross-section view, partial and simplified, of a structure obtained at the end of a step of deposition of a layer 51′ on the upper surface of the structure illustrated in FIG. 2G. More particularly, layer 51′ is formed so as to cover the entire upper surface of the structure illustrated in FIG. 2G. Layer 51′ covers, for example, the upper surface of layer 45′ and the upper surface of vias 63. Layer 51′ is made of the same material as the layer 51 of FIGS. 1A and 1B. Layer 51′ has a thickness substantially equal to the thickness of the layer 51 of FIGS. 1A and 1B.

FIG. 2I shows a cross-section view, partial and simplified, of a structure obtained at the end of a step of removal of a portion of layer 51′ to form openings 81 in layer 51′. As an example, in openings 81, the upper surface of vias 63 is exposed. As an example, the local removal of layer 51′ is carried out by etching. As an example, during this step, only the portions of layer 51′ located in front of vias 63 are removed. As an example, the openings 81 formed in layer 51′ have a shape corresponding to the shape of the heating elements 49 illustrated in FIGS. 1A and 1B. As an example, the openings 81 in layer 51′ correspond to vertical trenches. As a variant, the openings 81 in layer 51 have an “L” shape, in which the horizontal portion extends over the upper surface of vias 63 and the vertical portion corresponds to a trench. As an example, openings 81 are local and do not extend in the bit line direction.

FIG. 2J shows a cross-section view, partial and simplified, of a structure obtained at the end of a step of filling of openings 81 to form heating elements 49. As an example, in a first phase, during this step, a layer made of the material of heating elements 49 is for example deposited on the upper surface of the structure illustrated in FIG. 21 and more precisely on the upper surface of layer 51 and in openings 81. During this step, in a second phase, the upper surface of the structure is for example submitted to a polishing, to expose the upper surface of layer 51 and only leave the layer of heating element material 49 in openings 81, and thus form heating elements 49.

FIG. 2K shows a cross-section view, partial and simplified, of a structure obtained at the end of a step of deposition of a layer 47′, made of the phase-change material of the layer 47 of FIGS. 1A and 1B, and of a conductive layer 53′, made of the material of the layer 53 of FIGS. 1A and 1B, on the upper surface of the structure illustrated in FIG. 2J. As an example, during this step, a layer made of phase-change material 47′ is formed on the upper surface of the structure illustrated in FIG. 2J. The layer 47′ of phase-change material is for example formed in contact with layer 49. During this step, layer 53′ is further formed on the upper surface of the layer 47′ of the phase-change material. Layer 53′ is for example formed in contact with the layer 47′ of the phase-change material.

FIG. 2L illustrates a cross-section view, partial and simplified, of a structure obtained at the end of a step of individualization of the bit lines of memory cells M in layers 47′ and 49 and in layers 51′ and 53′, to form elements 49 and layers 47, 51, and 53. More specifically, during this step, there is formed, in front of the vias 63 of a same bit line, a stack in layers 47 and 49 and in metallization 53, to define the bit lines of memory cells M. This step is for example carried out by etching. As an example, at the end of this step, layer 51′ remains between the heating elements 49 of a same bit line, forming layer 51. At the end of this step, each memory cell is thus formed by a stack of layer 49, of layer 47, and of metallization 53. The forming of this stack after and above interconnection level 35 advantageously enables to do away with risks of contamination of the layer 47 of the memory cell generated by the forming of the interconnection stack and of the different metal levels 71 and 69.

FIG. 2M shows a cross-section view, partial and simplified, of a structure obtained at the end of a step of deposition of layer 55 on the upper surface of the structure illustrated in FIG. 2L. More specifically, during this step, layer 55 is formed on the upper surface of layer 45′ and on the upper surface and the flanks of the stacks formed in layers 47 and 49 and metallization 53, each defining a bit line of memory cells M.

FIG. 2N illustrates a cross-section view, partial and simplified, of a structure obtained at the end of a step of removal of the portions of layer 55 located on the upper surface of layer 45′ and of deposition of a layer 59 on the upper surface of the structure illustrated in FIG. 2M. Layer 59 is made of the same material as layer 45. More specifically, during this step, layer 59 is for example formed so that it covers the entire layer 45′ and the entire layer 55. Layer 59 is for example deposited with a thickness such that the bit lines of the memory cells M defined in relation with FIG. 2L are entirely covered by layer 59.

FIG. 2O shows a cross-section view, partial and simplified, of a structure obtained at the end of a step of planarization of the upper surface of the structure illustrated in FIG. 2N. This step is for example carried out by CMP. Layers 59 and 45′ then form layer 45.

FIG. 2P shows a cross-section view, partial and simplified, of a structure obtained after a step of forming of vias 68 and 70. As an example, this step includes a step of etching of layer 45 to form openings therein which are, in a successive step, filled with the material of vias 68 and 70.

The method then includes steps, not shown. More specifically, the process further includes the forming of interconnection stack 36 on the structure resulting from the step of FIG. 2P. The forming of stack 36 is, for example, similar to the forming of stack 35.

FIG. 3 shows an electronic device 90 according to another embodiment. Device 90 includes the elements of the device 11 of FIGS. 1A and 1B, which will not be described again in detail.

Device 90 differs from device 11 in that device 90 does not comprise vias 69d, that is, the conductive vias of the lower level of stack 36. Thus, tracks 71d extend from the lower surface of layer 39d to the upper surface of layer 37d. The upper surface of each via 68 or 70 is thus in contact with the lower surface of a track 71d.

An advantage of such a structure is that it is possible to form the connections of the level of stack 36 with a level having a low thickness.

The method of manufacturing device 90 is identical to the method described in relation with FIGS. 2A to 2P, except for the forming of stack 36, which does not comprise the forming of vias 69d.

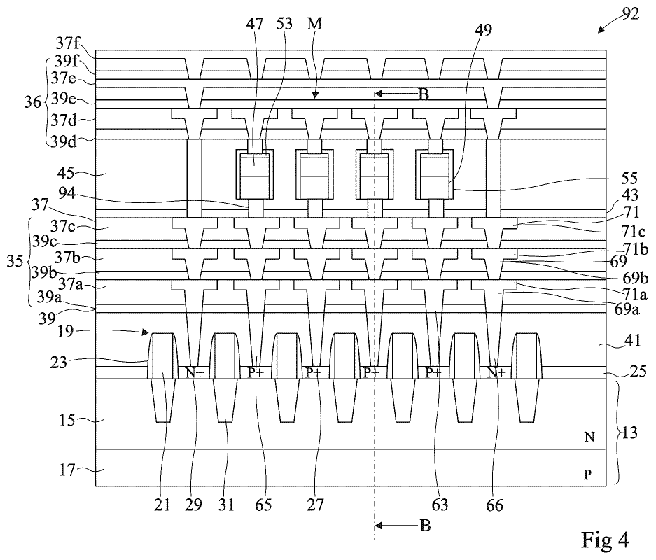

FIG. 4 shows an electronic device according to another embodiment 92. Device 92 includes the elements of the device 11 of FIGS. 1A and 1B, which will not be described again in detail.

Device 92 differs from device 11 in that the vias 63 of device 11 have each been replaced with a succession of conductive vias 69 and of conductive tracks 71. Thus, tracks 71a, 71b, 71c and vias 69a, 69b, 69c are located in front of each region 27 and in front of each memory cell M.

Device 92 further includes elements, or vias, 94. Vias 94 are for example made of the material of vias 68 and 70. Each via 94 extends from the upper surface of a track 71c to the lower surface of an element 49. Thus, each via 94 runs through layer 43 and the portion of layer 45 located under a memory cell M.

Each memory cell M is thus coupled to a region 27 via a via 94, tracks 71, and vias 69.

The method of manufacturing device 92 includes the steps of device 11, that is, the steps described in relation with FIGS. 2A to 2P. The method of manufacturing device 92 differs from the method of FIGS. 2A to 2P in that, at the step of FIG. 2C, the vias 69 and the tracks 71 located in front of regions 27 are formed, for example at the same time as the tracks 71 and the vias 69 of the same levels. Further, the method does not comprise the steps of FIGS. 2E to 2G. The method however includes, between the steps of FIGS. 2D and 2H, the forming of vias 94, for example by a damascene method.

An advantage of the described embodiments is that the absence of conductive tracks in layer 45 decreases the risk of parasitic capacitances. Accordingly, on one embodiment, the layer 45 does not include a material having a low dielectric constant.

An advantage of the present embodiments including vias 63 is that the lack of conductive tracks in the layers 37 diminish the risks of parasitic capacitances, facilitating forming layers 37 in a material other than a material having a low dielectric constant.

An advantage of the present embodiments is that it enables to do away with metal level sizing constraints for PCM cell integration, since the surface area of vias 63 can be smaller than the surface area of a track 71 at the surface of interconnection stack 35. This embodiment advantageously comprises no vias 69 and tracks 71.

Another advantage of the present embodiments vias 63 is that the forming of the memory cells above interconnection level 36 enables to do away with risks of contamination of the PCM layer of the memory cell generated by the forming of the interconnection stack and of the various metal levels 71 and 69.

Still another advantage of the present embodiment is that it is compatible with known methods and logic parts, the logic part not being impacted.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

In one embodiment, a device (11, 90, 92) includes a semiconductor substrate (13) having selection transistors arranged therein; a first interconnection stack (35), arranged on the semiconductor substrate (13), including at least one level, each level including first and second insulating layers (37, 39), having conductive tracks (71) and first conductive vias (69) defined therein; a third insulating layer (45), resting on the first interconnection stack (35); a second interconnection stack (36), arranged on the third insulating layer (45), including at least one level, each level including first and second insulating layers (37, 39), having the conductive tracks (71) and the first conductive vias (69) defined therein; a plurality of memory cells (M) arranged in the third insulating layer (45); and at least one second conductive via (70) extending along the entire height of the third insulating layer, so as to couple the conductive tracks and first conductive vias of the first and second stacks (35, 36).

In one embodiment, each memory cell (M) includes a resistive element (49) in contact with a fourth layer (47) made of a phase-change material, the seventh layer being topped with a fifth conductive layer (53).

In one embodiment, the semiconductor substrate (13) includes, from an upper surface, a sixth doped semiconductor layer (15) of a first conductivity type (N), located on top of and in contact with a seventh doped semiconductor layer (17) of a second conductivity type (P) opposite to the first conductivity type.

In one embodiment, the semiconductor substrate (13) is topped with an eighth semiconductor layer (25) including first doped areas (27) of the second conductivity type (P), each of the first areas of the eighth semiconductor layer (25) being coupled to a memory cell (M).

In one embodiment, the sixth semiconductor layer (15), the seventh semiconductor layer (17), and the first regions (27) of the sixth semiconductor layer (25) may form the selection transistors.

In one embodiment, the eighth semiconductor layer (25) includes second doped areas (29) of the first conductivity type (N), each of the second areas (29) of the eighth semiconductor layer (25) being coupled to a set of first conductive vias (69) and of conductive tracks (71) running through the interconnection stack (35).

In one embodiment, each of the first areas (27) of the eighth semiconductor layer (25) is coupled to a memory cell (M) by a single third via (63) extending along the entire height of the first stack (35).

In one embodiment, the third via is in contact with the resistive element of the memory cell.

In one embodiment, each of the first areas (27) of the eighth semiconductor layer (25) is coupled to a memory cell by conductive vias (69) and conductive tracks (71) of the first interconnection network (35) and by a fourth via (94) extending in the third layer (45) and being in contact with the resistive element of the memory cell, each fourth via being made of the same material as the second vias (70).

In one embodiment, the third layer (45) is made of a material different from the materials of the first and second insulating layers (37, 39).

In one embodiment, the material of the third layer (45) has a dielectric constant higher than those of the materials of the first and second layers.

In one embodiment, the height of the third layer (45) is greater than the heights of the levels of the first and second stacks (35, 36).

In one embodiment, the level of the second stack closest to the third layer only includes conductive tracks in contact with the third via (70).

In one embodiment, the conductive tracks (71) of the first and second stacks (35, 36) extend laterally over a surface area greater than the surface area of the first conductive vias (69) of the same level.

In one embodiment, a method of manufacturing an electronic device (11, 90, 92) includes: the forming of a semiconductor substrate (13) having selection transistors arranged therein; the forming of a first interconnection stack (35), arranged on the semiconductor substrate (13), including at least one level, each level including first and second insulating layers (37, 39), having conductive tracks (71) and first conductive vias (69) defined therein; the forming of a third insulating layer (45), resting on the first interconnection stack (35); the forming of a plurality of memory cells (M) arranged in the third insulating layer (45); the forming of a second interconnection stack (36), arranged on the third insulating layer (45), including at least one level, each level including first and second insulating layers (37, 39), having conductive tracks (71) and first conductive vias (69) defined therein; and the forming of at least one second conductive via (70) extending along the entire height of the third layer, so as to couple the conductive tracks and the first conductive vias of the first and second stacks (35, 36).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising:
a semiconductor substrate having a plurality of selection transistors arranged therein;
a first interconnection stack on the semiconductor substrate including at least one level, each level including first and second insulating layers having conductive tracks and first conductive vias defined therein;
a third insulating layer, resting on the first interconnection stack;
a second interconnection stack, arranged on the third insulating layer, including at least one level, each level including first and second insulating layers, having the conductive tracks and the first conductive vias defined therein;
a plurality of memory cells arranged in the third insulating layer; and
at least one second conductive via extending through an entire height of the third insulating layer and coupling the conductive tracks and first conductive vias of the first and second stacks.

2. The device according to claim 1, wherein each memory cell includes a resistive element in contact with a fourth layer made of a phase-change material, the seventh layer being topped with a fifth conductive layer.

3. The device according to claim 1, wherein the semiconductor substrate includes, from an upper surface, a sixth doped semiconductor layer of a first conductivity type, located on top of and in contact with a seventh doped semiconductor layer of a second conductivity type opposite to the first conductivity type.

4. The device according to claim 3, wherein the semiconductor substrate includes an eighth semiconductor layer including first doped areas of the second conductivity type, each of the first doped areas of the eighth semiconductor layer being coupled to a memory cell.

5. The device according to claim 4, wherein the sixth semiconductor layer, the seventh semiconductor layer, and the first regions of the sixth semiconductor layer form the selection transistors.

6. The device according to claim 4, wherein the eighth semiconductor layer includes second doped areas of the first conductivity type, each of the second areas of the eighth semiconductor layer being coupled to a set of first conductive vias and of conductive tracks running through the interconnection stack.

7. The device according to claim 4, wherein each of the first areas of the eighth semiconductor layer is coupled to a memory cell by a single third via extending along the entire height of the first stack.

8. The device according to claim 7, wherein each third via is in contact with the resistive element of the memory cell.

9. The device according to claim 2, wherein each of the first areas of the eighth semiconductor layer is coupled to a memory cell by the conductive vias and conductive tracks of the first interconnection network and by a fourth via extending in the third layer and being in contact with the resistive element of the memory cell, each fourth via being made of the same material as the second vias.

10. The device according to claim 1, wherein the third layer is made of a material different from the materials of the first and second insulating layers.

11. The device according to claim 1, wherein the material of the third layer has a dielectric constant higher than those of the materials of the first and second layers.

12. The device according to claim 1, wherein the height of the third layer is greater than the heights of the levels of the first and second stacks.

13. The device according to claim 1, wherein the height of the third layer is higher than the height of the memory cell.

14. The device according to claim 1, wherein the level of the second stack closest to the third layer only includes conductive tracks in contact with the third via.

15. The device according to claim 1, wherein the conductive tracks of the first and second stacks extend laterally over a surface area greater than the surface area of the first conductive vias of the same level.

16. The device according to claim 1, wherein the third layer is in a single material, the memory cells being entirely in the third layer.

17. The device according to claim 1, wherein the third layer includes not conductive tracks.

18. A method of manufacturing an electronic device comprising:
forming a semiconductor substrate having selection transistors arranged therein;
forming a first interconnection stack arranged on the semiconductor substrate and including at least one level, each level including first and second insulating layers having conductive tracks and first conductive vias defined therein;
forming a third insulating layer on the first interconnection stack;
forming a plurality of memory cells arranged in the third insulating layer;
forming a second interconnection stack, arranged on the third insulating layer, including at least one level, each level including first and second insulating layers having conductive tracks and first conductive vias defined therein; and
forming at least one second conductive via extending through an entire height of the third layer and coupling the conductive tracks and the first conductive vias of the first and second stacks.

19. The method of claim 18, wherein each memory cell includes a resistive element in contact with a fourth layer made of a phase-change material, the seventh layer being topped with a fifth conductive layer.

20. The method of claim 18, wherein the semiconductor substrate includes, from an upper surface, a sixth doped semiconductor layer of a first conductivity type, located on top of and in contact with a seventh doped semiconductor layer of a second conductivity type opposite to the first conductivity type.

21. The method of claim 20, wherein the semiconductor substrate includes an eighth semiconductor layer including first doped areas of the second conductivity type, each of the first doped areas of the eighth semiconductor layer being coupled to a memory cell.

22. A device, comprising:
a semiconductor substrate including first doped regions of a first conductivity type and second doped regions of a second conductivity type;
a first stack of first insulating layers on the semiconductor substrate;
a second insulating layer on the first stack of first insulating layers;
a plurality of memory cells in the second insulating layer;
a second stack of second insulating layers on the memory cells;
a first group of first conductive interconnection structures in the first stack of first insulating layers including a plurality of first metal tracks and first conductive vias electrically coupled to a first doped region of the plurality of first doped regions;
a plurality of second conductive vias each extending through an entirety of the first stack of insulating layers and coupling a respective memory cell to a second doped region; and
a third conductive via extending through an entirety of the second insulating layer and coupled to the first group of conductive interconnection structures.

23. The device of claim 22, comprising a second group of second conductive interconnection structures in the second stack of second insulating layers including a plurality of second metal tracks and second conductive vias electrically coupled to the third conductive via.
